(19) United States
(12) Patent Application Publication
(10) Pub. No.: US 2002/0190271 A1
(43) Pub. Date: Dec. 19, 2002

(54) InP heterojunction bipolar transistor with intentionally compressively mismatched base layer

(76) Inventor: Quesnell Hartmann, Champaign, IL (US)

Correspondence Address: BANNER & WITCOFF, LTD., TEN SOUTH WACKER DRIVE, SUITE 3000, CHICAGO, IL, 60606, US

(21) Appl. No.: 09/883,545

(22) Filed: Jun. 18, 2001

(51) Int. Cl. H01L 31/0328

(52) U.S. Cl. 257/197

(57) ABSTRACT

A heterojunction bipolar transistor (HBT) having a substrate formed of indium phosphide (InP) and having emitter, base and collector layers formed over the substrate such that the base layer is disposed between the emitter and collector layers. The collector layer formed from InGaAs, and the collector layer being doped n-type. The emitter layer formed from InP, and the emitter layer being doped n-type. The base layer formed of indium gallium arsenide (InGaAs), the base layer being compressively mismatched, and doped p-type. A lattice mismatch between the substrate and the base material is greater than 0.2%. In an x-ray rocking curve of the heterojunction bipolar transistor, a peak corresponding to the base layer being separated from a peak corresponding to the substrate layer by at least −250 arcseconds. In one embodiment this results from a percentage of indium in the base layer being greater than 54.5%, that is a lattice constant of the base layer is substantially larger than a lattice constant of the substrate throughout an entire base region.

A portion of the disclosure of this patent document contains material that is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

1. Field of the Invention

The present invention relates in general to high-speed electronic transistor devices, and more specifically to InP/InGaAs Heterojunction Bipolar Transistors (HBT).

2. Description of the Related Art

The emitter injection efficiency of a bipolar transistor is limited by the fact that carriers can flow from the base into the emitter region, over the emitter junction barrier, when the junction is under rearward bias. Such transistors use a lightly doped material for the base region and a heavily doped material for the emitter. The requirement of a lightly doped material for the base region results in undesirably high base resistances and a thick base region. It is known that for high frequency applications it is desirable to have a thin, heavily doped base and a lightly doped emitter. One solution is the heterojunction bipolar transistor. In these transistors the emitter injection efficiency can be increased without strict requirements on doping. Materials commonly used in heterojunction bipolar transistors include the aluminum gallium arsenide/galium arsenide (AlGaAs/GaAs) system because of the wide range of lattice matched compositions. It is also known to use a system where indium galium arsenide phosphide (InGaAsP) is grown on indium phosphide (InP).

Lattice matching is well known in the art and refers to matching of the lattice structure and lattice constant for two materials, for example galium arsenide and aluminum arsenide. Special consideration must be taken when depositing a material that has a lattice constant that is significantly different than the material on which it is being deposited. In the prior art, it is known that a thin layer is in compression or tension along the surface plane as its lattice constant adapts to the seed crystal. When this layer is grown very thick however, the layer eventually cannot maintain the compressive or tensile strain and it will relieve the strain by relaxing toward its natural lattice constant. This is the difference between a relaxed layer and a strained layer. The thickness at which a layer begins to relax is referred to as the critical thickness and it depends on the difference in the lattice parameter of the two materials. For indium galium arsenide on indium phosphide there is only one composition of indium galium arsenide that is exactly lattice matched. Since it is very difficult to get the exact match during crystal growth, it is considered in the prior art that if the latice mismatch is less than 0.2%, then the layers are considered to be lattice matched.

In the prior art galium arsenide grown on aluminum arsenide provided a large change in the band gap between the materials with little change in the lattice constant. Because they have similar lattice constants, they are thus easily grown one on top of another for any composition of aluminum galium arsenide. The system allows for band gap engineering without a designer being constrained by excessive strain or lattice relaxation since the mismatch was just less than 0.2%.

These materials such as described above allow for band gap engineering, which results in various types of desirable devices. In prior art typical heterojunction bipolar transistors are nominally lattice matched to the substrate lattice constant to avoid defects, stress and relaxation of the base material. These effects are generally viewed as harmful to the performance of heterojunction bipolar transistors and thus limit the designer's ability to engineer the band gap. Band gap engineering is used to design devices for different optical effects and electronic effects. The heterojunction bipolar transistor may be formed using MOVCD. MOCVD stands for stands for Metal Organic Chemical Vapor Deposition, a materials science technology used for growing compound semiconductor-based epitaxial wafers and devices. MOCVD technology is also known as OMVPE (Organo-Metal Vapor Phase Epitaxy) and MOVPE (Metal Organic Vapor Phase Epitaxy). Various epitaxial growth techniques are known in the prior art and include LPE (Liquid Phase Epitaxy) VPE (Vapor Phase Epitaxy) and MBE (Molecular Beam Epitaxy). MOCVD is a dominant growth technique behind the major devices and a popular choice of manufacturers involved in high volume production of epitaxial wafers and devices.

It is a drawback of the prior art that the lattice mismatch is to be kept less than 0.2% and thus there is a need in the prior art for a system for band gap engineering, which provides for devices having greater than 0.2% lattice mismatch.

### SUMMARY OF THE INVENTION

In general terms the present invention is a heterojunction bipolar transistor (HBT) having a substrate formed of indium phosphide (InP) and having emitter, base and collector layers formed over the substrate such that the base layer is disposed between the emitter and collector layers. In one embodiment, the collector layer is formed from InGaAs, and the collector layer being doped n-type. The emitter is layer formed from InP, and the emitter layer being doped n-type. The base layer is formed of indium gallium arsenide (InGaAs), the base layer being compressively mismatched, and doped p-type. A lattice mismatch between substrate and base material is greater than 0.2%. In an x-ray rocking curve of the heterojunction bipolar transistor, a peak corresponding to the base layer being separated from a peak corresponding to the substrate layer by at least −250 arcseconds. In one embodiment this results from a percentage of indium in the base layer being greater than 54.5%, that is the lattice constant of the base layer is substantially larger than the lattice constant of the substrate throughout the entire base region.

More specifically, the base layer is intentionally lattice mismatched so that the lattice constant of the base is substantially larger than that of the substrate material. From an x-ray rocking curve of an InP/InGaAs hetorojunction bipolar transistor with an intentionally mismatched base layer, the base layer peak displays a splitting of −975 arcseconds from the substrate peak. Assuming the layer is fully strained, this splitting corresponds to a perpendicular lattice mismatch of 7,734 ppm (0.7734%), a perpendicular lattice constant of 5.9142 angstroms and a composition of In_{0.588}Ga_{0.412}As. The lattice constant of the InP substrate is 5.8688 ang. This composition results in base layer having a smaller band gap than a base layer composed of the lattice matched composition (In_{0.53}Ga_{0.47}As). The smaller band gap will increase the size of heterojunction discontinuity, ΔE_{g}, of the emitter-base junction and introduce a heterojunction at the base-collector junction. These changes impact device operation.

### BRIEF DESCRIPTION OF THE DRAWINGS

The features of the present invention which are believed to be novel, are set forth with particularity in the appended claims. The invention, together with further objects and advantages, may best be understood by reference to the following description taken in conjunction with the accompanying drawings, in the several Figures of which like reference numerals identify like elements, and in which:

FIG. 1 is a cross sectional view of a heterojunction bipolar transistor according to the present invention.

FIG. 2 is an energy band diagram for a prior art heterojunction bipolar transistor.

FIG. 3 is an energy band diagram for a heterojunction bipolar transistor according to the present invention.

FIG. 4 is an X-ray rocking curve of the FIG. 3 heterojunction bipolar transistor of the present invention.

### DETAILED DESCRIPTION OF THE PREFERRED EMBODIMENTS

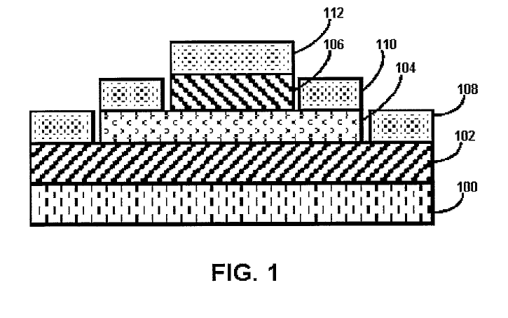

FIG. 1 is a cross-sectional view of a heterojunction bipolar transistor constructed according to the present invention. As depicted in FIG. 1 a substrate 100 (such as formed of InP) has a collector 102 on a first surface thereof. On the collector 102 is a base 104, and on the base 104 is an emitter 106. Each of the collector 102, the base 104 and the emitter 106 has respective metallic contacts 108, 110 and 112. Although the collector layer 102 is shown in FIG. 1 as being disposed between the base layer 104 and the substrate 100, it is within the scope of the present invention to reverse the positions of the collector 102 and the emitter 106. The heterojunction bipolar transistor depicted in FIG. 1 may be fabricated using conventional technology as is known in the art.

The substrate 100, the collector layer 102, the base layer 104 and the emitter layer 106 has the following thicknesses in one embodiment of the present invention:

Substrate layer 100 is in the range of 200 nm to 1000 nm;

Collector layer 102 is in the range of 100 nm to 50000 nm;

Base layer 104 is in the range of 10 nm to 200 nm; and

Emitter layer 106 is in the range of 20 nm to 200 nm.

In an embodiment of the present invention, a percentage of indium in the base layer is greater than 54.5%.

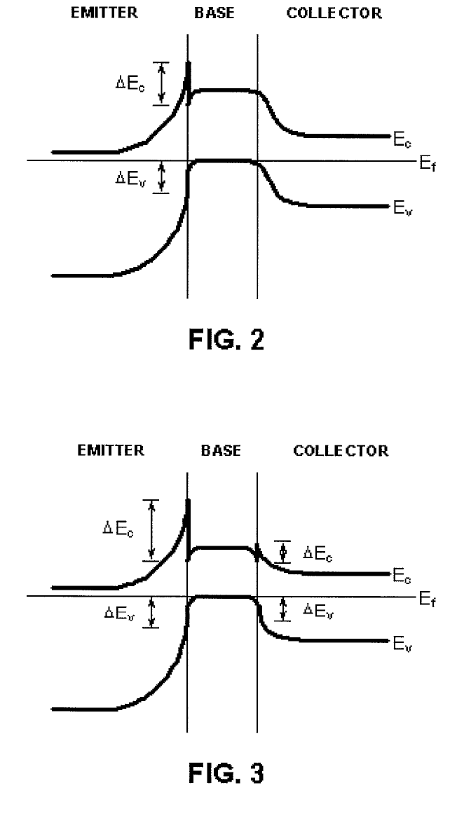

FIG. 2 depicts a typical prior art heterojunction bipolar transistor in terms of an energy band diagram. The energy band diagram is for a standard InP/InGaAs heterojunction bipolar transistor. For an InP emitter layer the ΔE_{c} is around 240 mV and the ΔEᵥ is around 330 mV. For an InAlAs emitter layer the ΔE_{c} is around 460 mV and the ΔEᵥ is around 200 mV. The ΔE_{c} is the conduction band discontinuity, and the ΔEᵥ is the valance band discontinuity and ΔE_{c} and ΔEᵥ are referenced to the equilibrium fermi level E_{f}.

FIG. 3 is an energy band diagram of an intentionally lattice mismatched base heterojunction bipolar transistor according to the present invention. As depicted in FIG. 3 the band gap of the base layer decreases, while the ΔE_{c} at the emitter based junction gets larger compared with the standard lattice matched structure as depicted in FIG. 2. A heterojunction also forms at the base collector junction. The size of the heterojunction discontinuities at the emitter base and collector base junctions depends on the exact composition of the base layer.

The novelty of the use of highly mismatched material as the base layer of an HBT is due to the underlying assumption that strain, strain relaxation and defects would result in degraded device performance such as current gain due to enhanced intrinsic base recombination current. In fact, the current gain does not show signs of degradation when the base layer is significantly mismatched from the rest of the device layers. This allows more flexibility in designing the bandgap of the base layer as depicted in FIGS. 2 and 3.

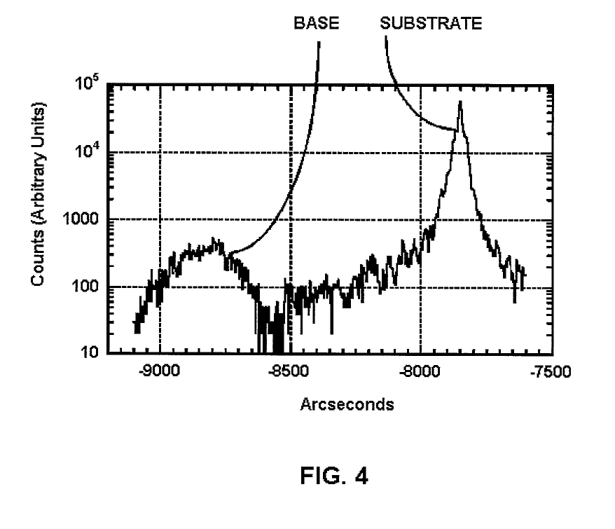

FIG. 4 is an X-ray rocking curve of the InP/InGaAs heterojunction bipolar transistor according the present invention. As can be seen in the FIG. 4 graph, the base layer displays a splitting of −975 arcseconds from the substrate peak. The measurement was taken of the (004) symmetric reflection using the double crystal X-ray diffraction technique and the Cu Kα x-ray emission. The splitting corresponds to a perpendicular lattice mismatch of 7,734 ppm (0.7734%), which is a perpendicular lattice constant of 5.9142 ang. The lattice constant of the InP substrate is 5.8688 ang. The rest of the layers (collector and emitter) are lattice matched to the substrate and cannot be easily differentiated from the substrate in this measurement.

An important feature of the present invention is that the band gap is modifiable with regards to the base material and the emitter base junction characteristics. Compressively mismatched base material has important advantages in this device, namely a smaller base band gap, improvements in charge carrier characteristics, and improved device lifetime. A smaller band gap in the base will reduce the threshold voltage of the device, requiring less power to turn on the device than the typical prior art devices with lattice matched material. As with compressively strained quantum well AlGaAs/GaAs/InGaAs lasers, this invention may significantly improve the device lifetime. Also, the change in minority and majority carrier mobility, diffusion lengths and lifetimes will enhance both DC and RF performance, giving the designer greater flexibility in engineering the characteristics of the heterojunction bipolar transistor.

The invention is not limited to the particular details of the apparatus depicted and other modifications and applications are contemplated. Certain other changes may be made in the above described apparatus without departing from the true spirit and scope of the invention herein involved. Also encompassed by the present invention are InAlAs/InGaAs heterojunction bipolar transistors in which the InP emitter layer is replaced with InAlAs or InAlGaAs. Double heterojunction devices in which the InGaAs collector material is completely or partially replaced with a wider bandgap material like InP, InGaAsP, InAlAs or InAlGaAs are also comtemplated. Different base materials such as GaAsSb are also contemplated by the present invention. It is intended, therefore, that the subject matter in the above depiction shall be interpreted as illustrative and not in a limiting sense.

I claim:

1. A heterojunction bipolar transistor (HBT), comprising:
a substrate formed of indium phosphide (InP); emitter, base and collector layers formed over the substrate such that the base layer is disposed between the emitter and collector layers; the collector layer formed from InGaAs, and the collector layer being doped n-type; the emitter layer formed from InP, and the emitter layer being doped n-type; the base layer formed of indium gallium arsenide (InGaAs), the base layer being compressively mismatched, and the base layer being doped p-type; and a lattice mismatch between the substrate and the base material being greater than 0.2%.

2. The heterojunction bipolar transistor according to claim 1, wherein the substrate is semi-insulating.

3. The heterojunction bipolar transistor according to claim 1, wherein the collector layer is disposed between the substrate and the base layer.

4. The heterojunction bipolar transistor according to claim 1, wherein in an x-ray rocking curve of the heterojunction bipolar transistor, a peak corresponding to the base layer being separated from a peak corresponding to the substrate layer by at least −250 arcseconds.

5. The heterojunction bipolar transistor according to claim 1, wherein a percentage of indium in the base layer is greater than 54.5%.

6. The heterojunction bipolar transistor according to claim 1, wherein a lattice constant of the base layer is substantially larger than a lattice constant of the substrate throughout an entire base region of the base layer.

7. A heterojunction bipolar transistor (HBT), comprising:
a substrate formed of indium phosphide (InP);
emitter, base and collector layers formed over the substrate such that the base layer is disposed between the emitter and collector layers;
the collector layer formed from InGaAs, and the collector layer being doped n-type;
the emitter layer formed from InP, and the emitter layer being doped n-type;
the base layer formed of indium gallium arsenide (InGaAs), the base layer being compressively mismatched, and the base layer being doped p-type; and
in an x-ray rocking curve of the heterojunction bipolar transistor, a peak corresponding to the base layer being separated from a peak corresponding to the substrate layer by at least −250 arcseconds.

8. The heterojunction bipolar transistor according to claim 7, wherein the substrate is semi-insulating.

9. The heterojunction bipolar transistor according to claim 7, wherein the collector layer is disposed between the substrate and the base layer.

10. The heterojunction bipolar transistor according to claim 7, wherein a percentage of indium in the base layer is greater than 54.5%.

11. The heterojunction bipolar transistor according to claim 7, wherein a lattice constant of the base layer is substantially larger than a lattice constant of the substrate throughout an entire base region of the base layer.

12. A heterojunction bipolar transistor (HBT), comprising:
a substrate formed of indium phosphide (InP);
emitter, base and collector layers formed over the substrate such that the base layer is disposed between the emitter and collector layers;
the collector layer formed from InGaAs, and the collector layer being doped n-type;
the emitter layer formed from InP, and the emitter layer being doped n-type;
the base layer formed of indium gallium arsenide (InGaAs), the base layer being compressively mismatched, and the base layer being doped p-type; and
a percentage of indium in the base layer being greater than 54.5%.

13. The heterojunction bipolar transistor according to claim 12, wherein the substrate is semi-insulating.

14. The heterojunction bipolar transistor according to claim 12, wherein the collector layer is disposed between the substrate and the base layer.

15. The heterojunction bipolar transistor according to claim 12, wherein in an x-ray rocking curve of the heterojunction bipolar transistor, a peak corresponding to the base layer being separated from a peak corresponding to the substrate layer by at least −250 arcseconds.

16. The heterojunction bipolar transistor according to claim 12, wherein a lattice constant of the base layer is substantially larger than a lattice constant of the substrate throughout an entire base region.

17. A heterojunction bipolar transistor (HBT), comprising:
a substrate formed of indium phosphide (InP);
emitter, base and collector layers formed over the substrate such that the base layer is disposed between the emitter and collector layers;
the collector layer formed from InGaAs, and the collector layer being doped n-type;
the emitter layer formed from InP, and the emitter layer being doped n-type;
the base layer formed of indium gallium arsenide (InGaAs), the base layer being compressively mismatched, and the base layer being doped p-type; and
the lattice constant of the base layer being substantially larger than a lattice constant of the substrate throughout an entire base region of the base layer.

18. The heterojunction bipolar transistor according to claim 17, wherein the substrate is semi-insulating.

19. The heterojunction bipolar transistor according to claim 17, wherein the collector layer is disposed between the substrate and the base layer.

20. The heterojunction bipolar transistor according to claim 17, wherein in an x-ray rocking curve of the heterojunction bipolar transistor, a peak corresponding to the base layer being separated from a peak corresponding to the substrate layer by at least 250 arcseconds.

21. The heterojunction bipolar transistor according to claim 17, wherein a percentage of indium in the base layer is greater than 54.5%.
